(19) United States
(12) Patent Application Publication
(10) Pub. No.: US 2016/0239148 A1
(43) Pub. Date: Aug. 18, 2016

(54) METHOD OF CONTROLLING ACTIVATION AREA OF TOUCH SCREEN PANEL AND ELECTRONIC DEVICE USING THE SAME

(71) Applicant: Samsung Electronics Co., Ltd., Gyeonggi-do (KR)

(72) Inventors: Jeong-Jin Lee, Seoul (KR); Mooyoung Kim, Seoul (KR); Young Mok Kim, Seoul (KR)

(21) Appl. No.: 15/046,278

(22) Filed: Feb. 17, 2016

(30) Foreign Application Priority Data
Feb. 17, 2015 (KR) 10-2015-0024459

(51) Int. Cl. G06F 3/041; H05K 5/03

(52) U.S. Cl. CPC G06F 3/0416; H05K 5/03

(57) ABSTRACT

A method of controlling an activation area of a touch screen panel and an electronic device using the same. A method of operating an electronic device, according to an embodiment of the present disclosure, may include: setting a partial area of a touch screen panel, which corresponds to a view window of a cover that is mounted on the electronic device, as an effective touch area when the cover is closed; and when the cover mounted on the electronic device is closed, activating the partial area of the touch screen panel that corresponds to the set effective touch area. In addition, the various embodiments of the present disclosure also include other embodiments as well as the above-described embodiment.

### CROSS-REFERENCE TO RELATED APPLICATION AND CLAIM OF PRIORITY

The present application is related to and claims benefit under 35 U.S.C. §119(a) to Korean Application Serial No. 10-2015-0024459, which was filed in the Korean Intellectual Property Office on Feb. 17, 2015, the entire content of which is hereby incorporated by reference.

### TECHNICAL FIELD

Various embodiments of the present disclosure relate to a method of controlling an activation area of a touch screen panel and an electronic device using the same.

### BACKGROUND

In general, various types of electronic devices, such as smart phones, tablet PCs, etc., have been widely used. With the wide use of electronic devices, users have been increasingly interested in various forms of external accessories that may be mounted on the electronic devices.

External accessories may include cover products for protecting the bodies and Touch Screen Panels (TSPs) of electronic devices. For example, the covers protect the bodies, the touch screen panels, etc. of the electronic devices, and operate in conjunction with the electronic devices through electrical signals such that the electronic devices provide arbitrary assistance functions.

### SUMMARY

To address the above-discussed deficiencies, it is a primary object to provide a method of controlling an activation area of a touch screen panel and an electronic device using the same that can activate a partial area of the touch screen panel, which corresponds to a view window of a cover that is mounted on the electronic device, as an effective touch area when the cover is closed.

According to the various embodiments of the present disclosure, a method of operating an electronic device may include: setting a partial area of a touch screen panel, which corresponds to a view window of a cover that is mounted on the electronic device, as an effective touch area when the cover is closed; and when the cover mounted on the electronic device is closed, activating the partial area of the touch screen panel that corresponds to the set effective touch area.

According to the various embodiments of the present disclosure, an electronic device may include: a touch screen panel; a controller configures to control the touch screen panel; and a processor coupled to the controller, wherein the processor is configured to set a partial area of the touch screen panel, which corresponds to a view window of a cover that is mounted on the electronic device, as an effective touch area when the cover is closed; and activate the partial area of the touch screen panel, which corresponds to the set effective touch area, in conjunction with the controller when the cover, which is mounted on the electronic device is closed.

According to the various embodiments of the present disclosure, a partial area of a touch screen panel that corresponds to a view window of a cover that is mounted on an electronic device can be activated as an effective touch area when the cover is closed, thereby preventing unnecessary power consumption and inefficient signal processing and efficiently corresponding to various types of view windows that have different arbitrary shapes, sizes, and location coordinates.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a diagram illustrating an electronic device equipped with a cover;

FIG. 2 is a diagram illustrating the first touch processing method for the electronic device equipped with the cover;

FIG. 3 is a diagram illustrating the second touch processing method for the electronic device equipped with the cover;

FIGS. 4A to 4C are block diagrams of an electronic device, according to various embodiments of the present disclosure;

FIG. 5 is a flowchart illustrating a method of controlling an activation area of a touch screen panel according to an embodiment of the present disclosure;

FIG. 6 is a block diagram of an electronic device according to another exemplary embodiment of the present disclosure;

FIG. 7 is a flowchart illustrating a method of controlling an activation area of a touch screen panel according to another embodiment of the present disclosure;

FIG. 8 is a diagram illustrating a method of recognizing a view window of a cover according to various embodiments of the present disclosure;

FIG. 9 is a diagram illustrating another method of recognizing a view window of a cover according to various embodiments of the present disclosure;

FIG. 10 is a diagram illustrating a method of processing an input touch according to various embodiments of the present disclosure;

FIG. 11 is a diagram illustrating a difference in resolution between a view window image and a touch screen panel according to various embodiments of the present disclosure;

FIG. 12 is a diagram illustrating a view window image that is converted to have a low resolution and effective touch area information of a touch screen panel according to various embodiments of the present disclosure; and

FIG. 13 is a block diagram of the whole configuration of an electronic device according to various embodiments of the present disclosure.

### DETAILED DESCRIPTION

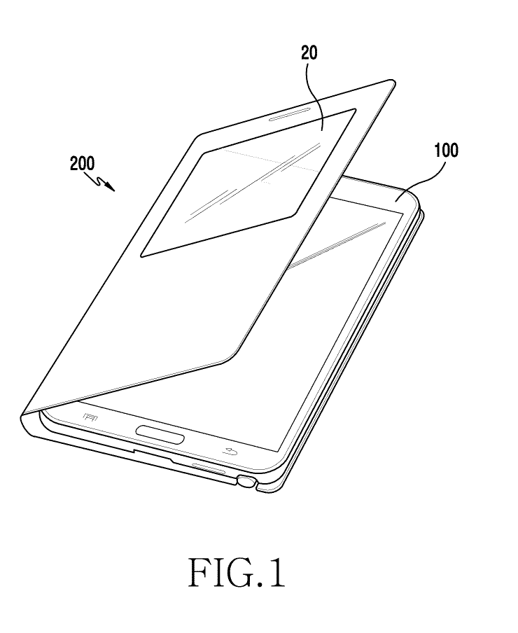

FIGS. 1 through 13, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device. Hereinafter, the present disclosure is described with reference to the accompanying drawings. The present disclosure may be changed variously and have various embodiments, and specific embodiments are exemplarily described and related detailed descriptions are made in the present specification. However, it should be understood that the various embodiments of the present disclosure are not limited to a specific embodied form and include all modifications and/or equivalents or substitutions that fall within the spirit and technical scope of the present disclosure. In the drawing, like reference numerals are used for like elements.

FIG. 1 is a diagram illustrating an electronic device equipped with a cover. Referring to FIG. 1, the electronic device 100 may be a portable terminal, such as a smart phone, etc., and the cover 200, which is one of the various forms of external accessories that may be mounted on the electronic device 100, may operate in conjunction with the electronic device 100 through an electrical signal.

The cover 200 may have, for example, a rectangular view window 20 formed therein, and the view window 20 may be formed in various forms, such as a circle, a heart, etc., on a portion of the front of the cover 200. The view window 20 may also be diversely referred to as different arbitrary names, such as, for example, a touch window, etc.

The view window 20 may be covered with, for example, a transparent conductive material that is widely used as a protection film of a touch screen panel, or may be a simple hole that is not covered with anything. When the front of the electronic device 100 is overlaid with the cover 200, a user can view a partial area of the display screen of the electronic device 100 only through the view window 20.

Further, the user may execute a desired operation by touching a partial area of the Touch Screen Panel (TSP) of the electronic device 100 only through the view window 20. Namely, even though the user unconsciously touches a portion of the cover other than the view window 20, the electronic device does not detect the touch as a touch input, thereby preventing an unnecessary operation from being executed irrespective of the user's intention.

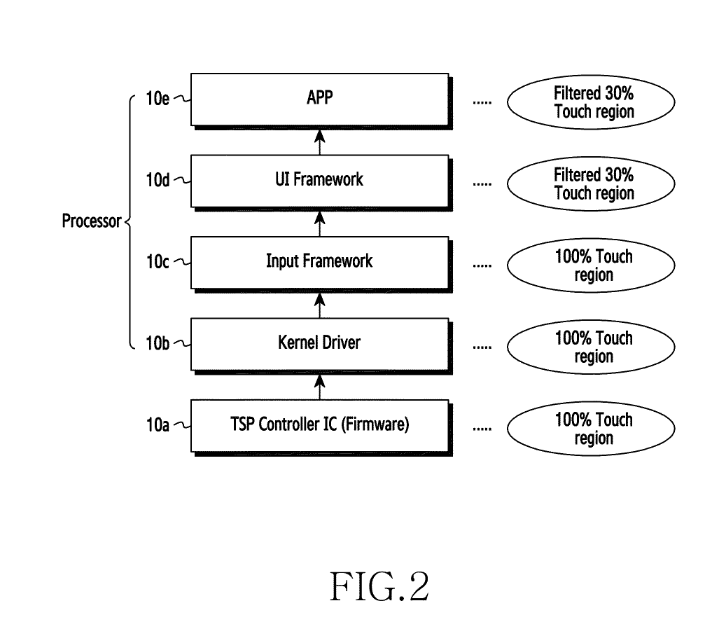

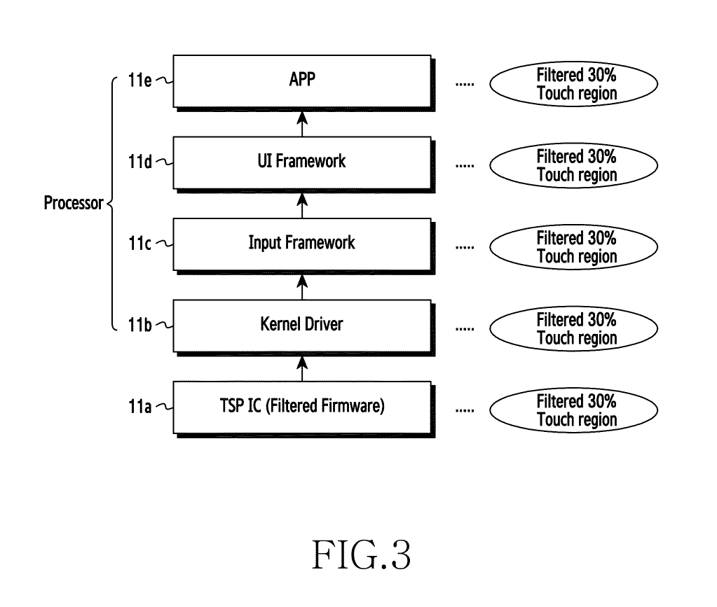

For example, there may be two touch processing methods in which a user executes a desired operation by touching a partial area of the touch screen panel (TSP) only through the view window 20 as described above. Hereinafter, the two touch processing methods will be described with reference to FIGS. 2 and 3.

FIG. 2 is a diagram illustrating the first touch processing method for the electronic device that is equipped with the cover. The electronic device 100 may be a smart phone, etc., and the electronic device 100 may include a touch screen panel (TSP), a TSP controller IC that controls the touch screen panel, a processor that operates in conjunction with the TSP controller IC, etc.

Referring to FIG. 2, the processor may have a stacked structure in which a kernel driver, an input framework, a UI framework, an application, etc. are operated in conjunction with each other with software. The TSP controller IC 10a, and the kernel driver 10b and the input framework 10c of the processor continually maintain an effective touch area for the touch screen panel (TSP) as it is even though the cover 200, which is mounted on the electronic device 100, is closed.

In contrast, the framework 10d and the application 10e of the processor may restrict the effective touch area for the touch screen panel (TSP) to a smaller area than the original size thereof through filtering. For example, the framework 10d and the application 10e of the processor may restrict the effective touch area for the touch screen panel (TSP) to 30% thereof through filtering in order to correspond to the shape, size, location coordinates, etc. of the view window 20, which is forming in the cover 200.

Accordingly, a user may execute a desired operation by touching a partial area (e.g., 30%) of the touch screen panel (TSP) only through the view window 20. However, in this case, power may be unnecessarily consumed, and signals may be inefficiently processed since the TSP controller IC 10a, and the kernel driver 10b and the input framework 10c of the processor continually maintain the effective touch area for the touch screen panel (TSP) as it is while the cover 200, which is mounted on the electronic device 100, is closed.

FIG. 3 is a diagram illustrating the second touch processing method for the electronic device equipped with the cover. The electronic device 100 may be a smart phone, etc., and the electronic device 100 may include a touch screen panel (TSP), a TSP controller IC that controls the touch screen panel, a processor that operates in conjunction with the TSP controller IC, etc. Referring to FIG. 3, the processor may have a stacked structure in which a kernel driver, an input framework, a UI framework, an application, etc. are operated in conjunction with each other in software.

When the cover 200 is closed, the TSP controller IC 11a, the kernel driver 11b, the input framework 11c, the UI framework 11d, and the application 11e may all restrict an effective touch area for the touch screen panel (TSP) to a smaller area than the original size thereof. For example, all of them may restrict the effective touch area for the touch screen panel (TSP) to 30% thereof through filtering in order to correspond to the shape, size, location coordinates, etc. of the view window 20, which is formed in the cover 200.

Accordingly, a user may execute a desired operation by touching a partial area (e.g., 30%) of the touch screen panel (TSP) only through the view window 20. However, in this case, it is impossible to efficiently correspond to various types of view windows that have different arbitrary shapes, sizes, location coordinates, etc. since the TSP controller IC 11a has to be fixed in the firmware in advance in order to restrict only the partial area (e.g., 30%) of the touch screen panel (TSP) to the effective touch area.

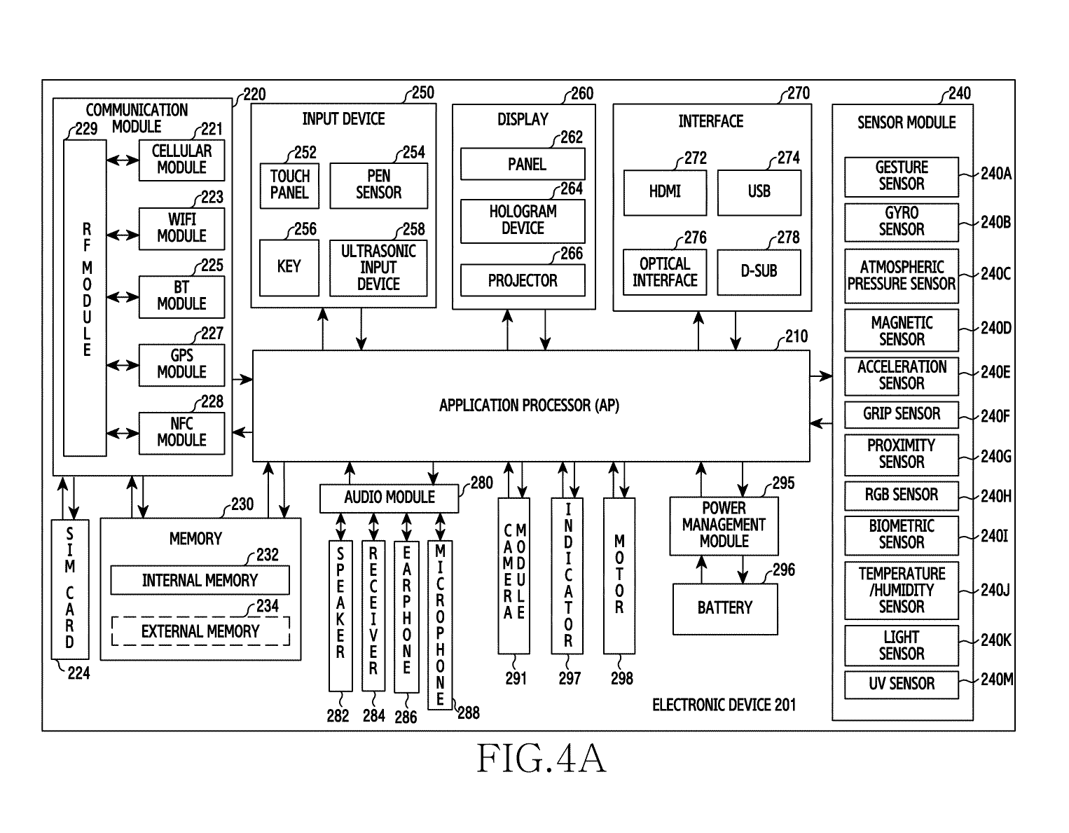

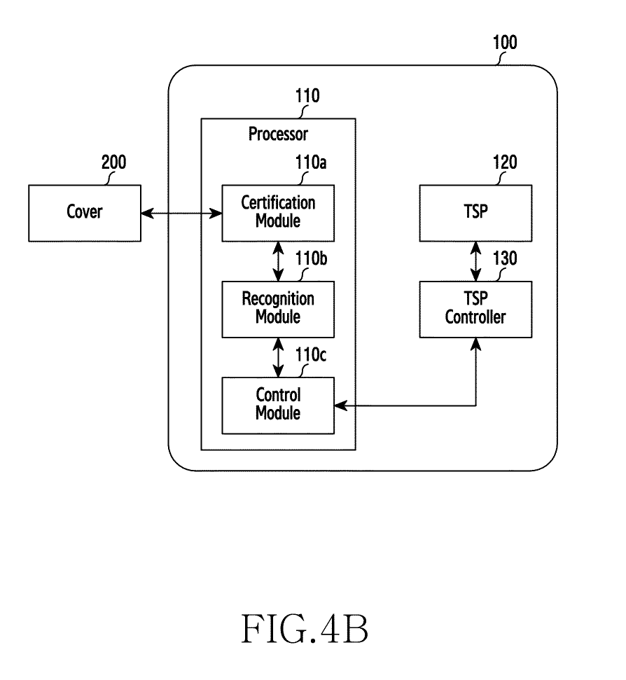

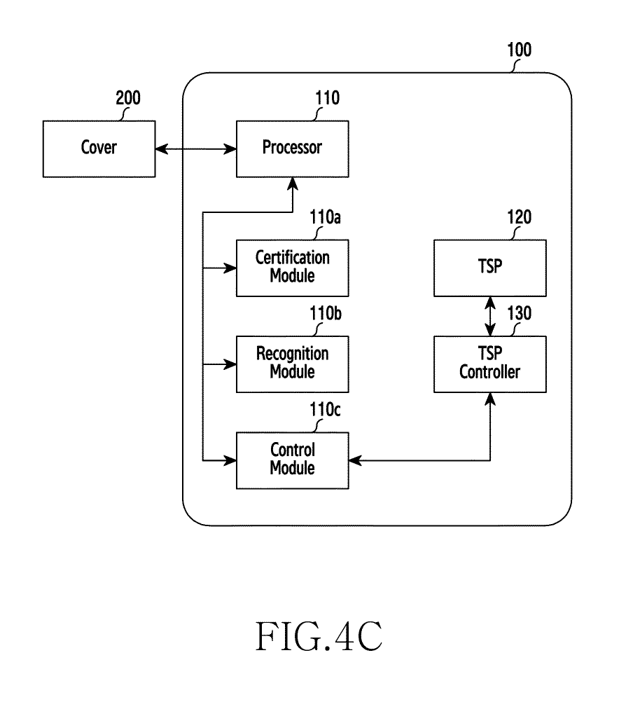

FIG. 4A is a block diagram of an example of an electronic device 201, according to various embodiments of the present disclosure. The electronic device 201 may configure, for example, all or a portion of the electronic device 101 illustrated in FIG. 1. Referring to FIG. 4A, the electronic device 201 may include one or more application processors (AP) 210, a communication module 220, a subscriber identification module (SIM) card 224, a memory 230, a sensor module 240, an input unit 250, a display 260, an interface 270, an audio module 280, a camera module 291, a power management module 295, a battery 296, an indicator 297, or a motor 298.

The AP 210 may drive an OS or an application to control a plurality of hardware or software elements connected to the AP 210, and perform various data processes including multimedia data and operations. The AP 210 may be implemented, for example, as a system on chip (SoC). According to an embodiment, the AP 210 may further include a graphic processing unit (GPU) (not shown).

The communication module 220 (e.g., the communication interface 170) may perform data transmission/reception in communication between the electronic device 201 (e.g., the electronic device 101) and other electronic devices (e.g., the electronic device 102, 104 or the server 106) connected via a network. According to an embodiment, the communication module 220 may include a cellular module 221, a Wi-Fi module 223, a BT module 225, a GPS module 227, an NFC module 228, and a Radio Frequency (RF) module 229.

The cellular module 221 may provide voice communication, image communication, a short message service, or an Internet service, etc. via a communication network (e.g., LTE, LTE-A, CDMA, WCDMA, UMTS, WiBro, or GSM, etc.). Also, the cellular module 221 may perform discrimination and authentication of an electronic device within a communication network using, for example, a subscriber identity module (e.g., a SIM card 224). According to an embodiment, the cellular module 221 may perform at least a portion of functions that may be provided by the AP 210. For example, the cellular module 221 may perform at least a portion of a multimedia control function.

According to an embodiment, the cellular module 221 may include a communication processor (CP). Also, the cellular module 221 may be, for example, implemented as a SoC. Though elements such as the cellular module 221 (e.g., a communication processor), the memory 230, or the power management module 295, etc. are illustrated as elements separated from the AP 210 in FIG. 2, according to an embodiment, the AP 210 may be implemented to include at least a portion (e.g., the cellular module 221) of the above-described elements.

Each of the Wi-Fi module 223, the BT module 225, the GPS module 227, or the NFC module 228 may include, for example, a processor for processing data transmitted/received via a relevant module. Though the cellular module 221, the Wi-Fi module 223, the BT module 225, the GPS module 227, or the NFC module 228 are illustrated as separate blocks in FIG. 2, according to an embodiment, at least a portion (e.g., two or more elements) of the cellular module 221, the Wi-Fi module 223, the BT module 225, the GPS module 227, or the NFC module 228 may be included in one Integrated Circuit (IC) or an IC package. For example, at least a portion (e.g., a communication processor corresponding to the cellular module 221 and a Wi-Fi processor corresponding to the Wi-Fi module 223) of processors corresponding to each of the cellular module 221, the Wi-Fi module 223, the BT module 225, the GPS module 227, or the NFC module 228 may be implemented as one SoC.

The RF module 229 may perform transmission/reception of data, for example, transmission/reception of an RF signal. The RF module 229 may include, for example, a transceiver, a power amp module (PAM), a frequency filter, or a low noise amplifier (LNA), etc., though not shown. Also, the RF module 229 may further include a part for transmitting/receiving an electromagnetic wave on a free space in wireless communication, for example, a conductor or a conducting line, etc. Though FIG. 2 illustrates the cellular module 221, the Wi-Fi module 223, the BT module 225, the GPS module 227, and the NFC module 228 share one RF module 229, according to an embodiment, at least one of the cellular module 221, the Wi-Fi module 223, the BT module 225, the GPS module 227, or the NFC module 228 may perform transmission/reception of an RF signal via a separate RF module.

The SIM card 224 may be a card including a subscriber identify module, and may be inserted into a slot formed in a specific position of the electronic device. The SIM card 224 may include unique identity information (e.g., integrated circuit card identifier (ICCID)) or subscriber information (e.g., international mobile subscriber identity (IMSI)).

The memory 230 (e.g., the memory 130) may include a built-in memory 232 or an external memory 234. The built-in memory 232 may include, for example, at least one of a volatile memory (e.g., dynamic RAM (DRAM), static RAM (SRAM), synchronous dynamic RAM (SDRAM)) and a non-volatile memory (e.g., one-time programmable ROM (OTPROM), programmable ROM (PROM), erasable and programmable ROM (EPROM), electrically erasable and programmable ROM (EEPROM), mask ROM, flash ROM, NAND flash memory, NOR flash memory, etc.).

According to an embodiment, the built-in memory 232 may be a Solid State Drive (SSD). The external memory 234 may further include a flash drive, for example, compact flash (CF), secure digital (SD), micro secure digital (Micro-SD), mini secure digital (Mini-SD), extreme digital (xD), or a memory stick. The external memory 234 may be functionally connected to the electronic device 201 via various interfaces. According to an embodiment, the electronic device 201 may further include a storage device (or a storage medium) such as a hard drive.

The sensor module 240 may measure a physical quantity or detect an operation state of the electronic device 201, and convert the measured or detected information to an electric signal. The sensor module 240 may include, for example, at least one of a gesture sensor 240A, a gyro sensor 240B, an atmospheric pressure sensor 240C, a magnetic sensor 240D, an acceleration sensor 240E, a grip sensor 240F, a proximity sensor 240G, a color sensor 240H (e.g., RGB (red, green, blue) sensor), a living body sensor 240I, a temperature/humidity sensor 240J, an illuminance sensor 240K, or an ultra violet (UV) sensor 240M. Additionally or alternatively, the sensor module 240 may include, for example, an E-nose sensor (not shown), an electromyography (EMG) sensor (not shown), an electroencephalogram (EEG) sensor (not shown), an electrocardiogram (ECG) sensor (not shown), an infrared (IR) sensor (not shown), an iris sensor (not shown), or a fingerprint sensor (not shown), etc. The sensor module 240 may further include a control circuit for controlling at least one sensor belonging thereto.

The input unit 250 may include a touch panel 252, a (digital) pen sensor 254, a key 256, or an ultrasonic input unit 258. The touch panel 252 may recognize a touch input using at least one of capacitive, resistive, infrared, or ultrasonic methods. Also, the touch panel 252 may further include a control circuit. A capacitive touch panel may perform detection by a physical contact or proximity recognition. The touch panel 252 may further include a tactile layer. In this case, the touch panel 252 may provide a tactile reaction to a user.

The (digital) pen sensor 254 may be implemented using, for example, a method which is the same as or similar to receiving a user's touch input, or using a separate sheet for detection. The key 256 may include, for example, a physical button, an optical key or keypad. The ultrasonic input unit 258 is a unit for recognizing data by detecting a sound wave using a microphone (e.g., a microphone 288) in the electronic device 201 via an input tool generating an ultrasonic signal, and enables wireless recognition. According to an embodiment, the electronic device 201 may receive a user input from an external device (e.g., a computer or a server) connected to the communication module 220 using the communication module 220.

The display 260 (e.g., the display 150) may include a panel 262, a hologram device 264, or a projector 266. The panel 262 may be, for example, a liquid crystal display (LCD), or an active-matrix organic light-emitting diode (AM-OLED), etc. The panel 262 may be implemented, for example, such that it is flexible, transparent, or wearable. The panel 262 may be configured as one module together with the touch panel 252. The hologram device 264 may show a three-dimensional image in the air using interferences of light. The projector 266 may project light onto a screen to display an image. The screen may be positioned, for example, inside or outside the electronic device 201. According to an embodiment, the display 260 may further include a control circuit for controlling the panel 262, the hologram device 264, or the projector 266.

The interface 270 may include, for example, a high-definition multimedia interface (HDMI) 272, a universal serial bus (USB) 274, an optical interface 276, or a D-subminiature (D-sub) 278. The interface 270 may be included, for example, in the communication interface 170 illustrated in FIG. 1. Additionally or alternatively, the interface 270 may include, for example, a mobile high-definition link (MHL) interface, a secure digital (SD) card/multi-media card (MMC) interface, or an infrared data association (IrDA) standard interface.

The audio module 280 may convert a sound and an electric signal in dual directions. At least a partial element of the audio module 280 may be included, for example, in the I/O interface 150 illustrated in FIG. 1. The audio module 280 may process sound information input or output via, for example, a speaker 282, a receiver 284, an earphone 286, or a microphone 288, etc.

The camera module 291 is a device that may shoot a still image and a moving picture. According to an embodiment, the camera module 291 may include one or more image sensors (e.g., a front sensor or a rear sensor), a lens (not shown), an image signal processor (ISP) (not shown), or a flash (not shown) (e.g., an LED or xenon lamp).

The power management module 295 may manage the power supply of the electronic device 201. Though not shown, the power management module 295 may include, for example, a power management integrated circuit (PMIC), a charger integrated circuit (IC), or a battery or a battery or fuel gauge.

The PMIC may be mounted, for example, inside an integrated circuit or a SoC semiconductor. A charging method may be classified into a wired charging method and a wireless charging method. The charging IC may charge a battery and prevent overvoltage or overcurrent from being caused by a charger. According to an embodiment, the charging IC may include a charging IC for at least one of the wired charging method and the wireless charging method. The wireless charging method may be, for example, a magnetic resonance method, a magnetic induction method, or an electromagnetic wave method, etc., and may additionally include an additional circuit for wireless charging, for example, a circuit such as a coil loop, a resonance circuit, or a rectifier, etc.

The battery gauge may measure, for example, a remnant of the battery 296, a voltage, a current, or a temperature while charging. The battery 296 may store or generate electricity, and supply power to the electronic device 201 using the stored or generated electricity. The battery 296 may include, for example, a rechargeable battery or a solar battery.

The indicator 297 may display a specific state of the electronic device 201 or a portion thereof (e.g., the AP 210), for example, a booting state, a message state, or a charging state, etc. The motor 298 may convert an electric signal to mechanical vibration. Though not shown, the electronic device 201 may include a processor (e.g., a GPU) for supporting a mobile TV. The processor for supporting the mobile TV may process media data corresponding to standards, for example, such as digital multimedia broadcasting (DMB), digital video broadcasting (DVB), or a media flow, etc.

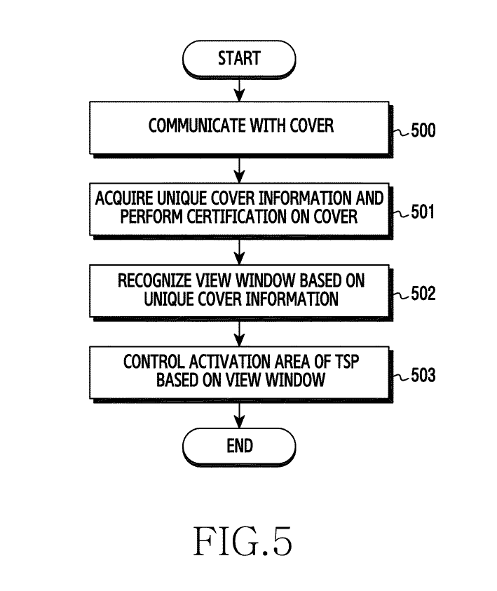

FIG. 4B is a block diagram of an electronic device according to an exemplary embodiment of the present disclosure. FIG. 4C is another block diagram of the electronic device according to the exemplary embodiment of the present disclosure. FIG. 5 is a flowchart illustrating a method of controlling an activation area of a touch screen panel according to an exemplary embodiment of the present disclosure.

Referring to FIG. 4B, the electronic device 100 may be, for example, a smart phone, etc. The electronic device 100 may include a processor 110, a touch screen panel 120, a TSP controller 130, etc., and the TSP controller 130 may be manufactured in various forms, such as an IC, a module, etc. that operates in conjunction with the processor 110. As described above with reference to FIG. 4A, the electronic device 100 may include various configurations, a pen sensor, an ultrasonic input device, etc.

The processor 110 may be operated in conjunction with an external accessory, for example a cover 200, which is mounted on the electronic device 100, by an electrical signal wherein the cover 200 has a view window formed therein. In cases where the electronic device 100 is equipped with the cover 200, the processor 110 may set a partial area of the touch screen panel 120, which corresponds to the view window of the cover 200, as an effective touch area when the cover 200 is closed. The processor 110 may operate in conjunction with the TSP controller 130 to activate only the partial area of the touch screen panel 120, which corresponds to the set effective touch area, when the cover 200 is closed.

As illustrated in FIG. 4B, the processor 110 may be functionally divided into a certification module 110a, a recognition module 110b, a control module 110c, etc. For example, the certification module 110a may certify whether the cover 200 is a genuine product or not through communication with the cover 200, and in cases where the cover 200 is a genuine product, the recognition module 110b may recognize the shape, size, location coordinates, etc. of the view window that is formed in the cover 200.

The control module 110c may set the partial area of the touch screen panel 120, which corresponds to the recognized view window, as an effective touch area when the cover 200 is closed, and may operate in conjunction with the TSP controller 130 to activate only the partial area of the touch screen panel 120, which corresponds to the set effective touch area, when the cover 200 is closed.

The modules 110a, 110b, and 110c may be diversely implemented in software, firmware, etc., and at least one of the modules 110a, 110b, and 110c may be installed as a separate element from the processor 110 to operate in conjunction with the processor 110. The processor 110 may be referred to as, for example, another arbitrary name, such as an application processor, etc. Referring to FIG. 4C, all or one of the modules 110a, 110b, and 110c may also be an external S/W module that is configured separately from the processor 110.

Referring to FIG. 5, in operation 500, the processor 110 may communicate with the cover 200 in cases where the electronic device 100 is equipped with the cover 200. For example, the processor 110 may acquire unique cover information, which is allocated to the cover 200, through the communication with the cover 200.

The unique cover information may include certification information required by the processor 110 to determine whether the cover 200 is a normal product that can electrically interwork with the electronic device 100. For example, the certification information may be a unique code, such as a serial number, etc. that the manufacturer of the cover 200 and the manufacturer of the electronic device 100 has assigned in advance.

Further, the unique cover information may include recognition information required by the processor 110 to recognize the shape, size, location coordinates, etc. of the view window formed in the cover 200. For example, the recognition information may be code values, for example the shape code, the size code, the location coordinate code, etc., which represent the shape, size, location coordinates, etc. of the view window formed in the cover 200, or may be image information that represents the shape, size, location coordinates, etc. of the view window at one time.

In operation 501, the processor 110 may certify whether the cover 200 is a genuine product or not based on the certification information included in the unique cover information. For example, if the certification information included in the unique cover information differs from the previously assigned unique certification information, the processor 110 may determine that the certification has failed and may allow an error message to be displayed.

In operation 502, if the certification information agrees with the previously assigned unique certification information, the processor 110 may perform a view window recognition operation of recognizing the shape, size, location coordinates, etc. of the view window, which is formed in the cover 200, based on the certification information included in the unique cover information.

For example, the processor 110 may recognize the view window formed in the cover 200 based on the shape code, the size code, the location coordinate code, etc. that are acquired as the certification information for the view window, or may recognize the view window formed in the cover 200 by scanning the image information that is acquired as the certification information for the view window.

In operation 503, the processor 110 may control an activation area for the touch screen panel 120 based on the recognized view window. For example, the processor 110 may set a partial area of the touch screen panel 120, which corresponds to the shape, size, location coordinates, etc. of the recognized view window, as an effective touch area when the cover 200 is closed, and thereafter, may operate in conjunction with the TSP controller 130 to activate only the partial area of the touch screen panel 120, which corresponds to the set effective touch area, when the cover 200 is closed.

Accordingly, when the cover 200 is closed, the processor 110 may restrict the effective touch area for the touch screen panel 120 to correspond to the view window of the cover 200, thereby preventing unnecessary power consumption and inefficient signal processing, and efficiently corresponding to various view windows that have different arbitrary shapes, sizes, location coordinates, etc.

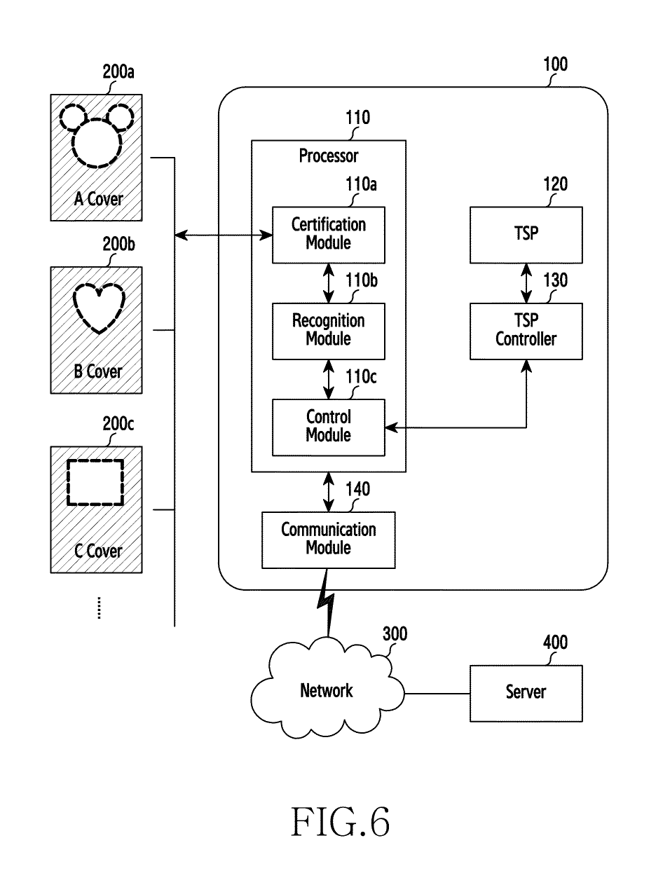

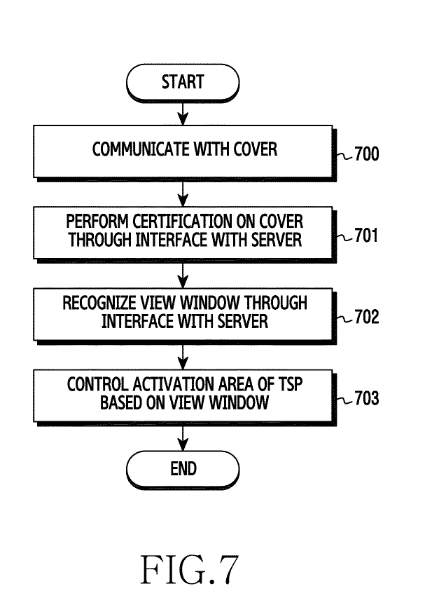

FIG. 6 is a block diagram of an electronic device according to another exemplary embodiment of the present disclosure, and FIG. 7 is a flowchart illustrating a method of controlling an activation area of a touch screen panel according to another exemplary embodiment of the present disclosure.

Referring to FIG. 6, the electronic device 100 may be, for example, a smart phone, etc. The electronic device 100 may include a processor 110, a touch screen panel 120, a TSP controller 130, a communication module 140, etc., and the TSP controller 130 may be manufactured in various forms, such as an IC, a module, etc. that operates in conjunction with the processor 110.

The processor 110 may be operated in conjunction with external accessories that are mounted on the electronic device 100, for example, covers 200a, 200b, and 200c that have various shapes of view windows formed therein as illustrated in FIG. 6, by electrical signals. In cases where the electronic device 100 is equipped with one of the covers, for example, the cover 200b that has a heart-shaped view window formed therein, the processor 110 may set a partial area of the touch screen panel 120, which corresponds to the view window of the cover 200b, as an effective touch area when the cover 200b is closed.

The processor 110 may operate in conjunction with the TSP controller 130 to activate only the partial area of the touch screen panel 120, which corresponds to the set effective touch area, when the cover 200b is closed.

As illustrated in FIG. 6, the processor 110 may be functionally divided into a certification module 110a, a recognition module 110b, a control module 110c, etc. For example, the certification module 110a may certify whether the cover 200b is a genuine product or not through communication with the cover 200b, and in cases where the cover 200b is a genuine product, the recognition module 110b may recognize the shape, size, location coordinates, etc. of the view window that is formed in the cover 200b.

Here, the function of certifying whether the cover is a genuine product or not and the function of recognizing the shape, size, location coordinates, etc. of the view window may be performed by an interface with a server 400, which is connected through a network 300, in conjunction with the communication module 140.

Further, as described above with reference to FIG. 4a, the functions may be performed by an interface with another electronic device or server, which is in a short range, through a short-range communication module, such as the Wi-Fi module 223, the Bluetooth module 225, etc.

The control module 110c may set the partial area of the touch screen panel 120, which corresponds to the recognized view window, as an effective touch area when the cover 200b is closed, and may operate in conjunction with the TSP controller 130 to activate only the partial area of the touch screen panel 120, which corresponds to the set effective touch area, when the cover 200b is closed.

The modules 110a, 110b, and 110c may be diversely implemented in software, firmware, etc., and at least one of the modules 110a, 110b, and 110c may be installed as a separate element from the processor 110 to operate in conjunction with the processor 110 as described above with reference to FIG. 4C. The processor 110 may be referred to as, for example, another arbitrary name, such as an application processor, etc.

Referring to FIG. 7, in operation 700, the processor 110 may communicate with the cover 200b in cases where the electronic device 100 is equipped with the cover 200b. For example, the processor 110 may acquire unique cover information, which is allocated to the cover 200b, through the communication with the cover 200b. Alternatively, through the communication with the cover 200b, the processor 110 may acquire URL information, etc. by which access to the cover information can be made.

The unique cover information may include certification information required by the processor 110 to determine whether the cover 200b is a normal product that can electrically interwork with the electronic device 100, through the interface with the server 400. For example, the certification information may be a unique code, such as a serial number, etc. that the manufacturer of the cover 200b and the manufacturer of the electronic device 100 has assigned in advance.

Further, the unique cover information may include recognition information required by the processor 110 to recognize the shape, size, location coordinates, etc. of the view window, which is formed in the cover 200b, through the interface with the server 400.

For example, the recognition information may be code values, for example the shape code, the size code, the location coordinate code, etc., which represent the shape, size, location coordinates, etc. of the view window formed in the cover 200b, or may be image information that represents the shape, size, location coordinates, etc. of the view window at one time.

In operation 701, the processor 110 may certify whether the cover 200b is a genuine product or not, through the interface with the server 400 based on the certification information included in the unique cover information. For example, the processor 110 may generate the certification information included in the unique cover information and a certification request message, and may transmit the generated certification information and certification request message to the server 400.

In response to the certification request message, the server 400 may identify whether the certification information of the cover 200b has been stored in, for example, a genuine-product certification database and thereafter, may generate a certification response message that corresponds to the identification result and transmit the generated certification response message to the processor 110. The processor 110 may allow an error message to be displayed when the certification response message shows that the certification has failed.

In operation 702, if the certification response message shows that the certification has succeeded, the processor 110 may perform a view window recognition operation of recognizing the shape, size, location coordinates, etc. of the view window, which is formed in the cover 200b, through the interface with the server 400 based on the recognition information included in the unique cover information.

For example, the processor 110 may transmit, to the server 400, the shape code, the size code, the location coordinate code, etc. that have been acquired as the recognition information for the view window, or may transmit, to the server 400, the image information that has been acquired as the recognition information for the view window. Further, the processor 110 may generate a recognition request message, in addition to the recognition information, and may transmit the same to the server 400.

In response to the recognition request message, the server 400 may set a partial area of the touch screen panel, which corresponds to the shape, size, location coordinates, etc. of the view window, as an effective touch area, and thereafter, may generate information on the effective touch area and a recognition response message and transmit the generated information and recognition response message to the processor 110 of the electronic device.

Meanwhile, according to the exemplary embodiment of the present disclosure, the electronic device may perform a procedure of downloading the recognition information for the view window from the server and setting an effective touch area based on the downloaded recognition information.

In operation 703, the processor 110 may control an activation area for the touch screen panel 120 based on the information on the effective touch area that is received together with the recognition response message. For example, when the cover 200b is closed, the processor 110 may operate in conjunction with the TSP controller 130 to activate only the partial area of the touch screen panel 120 that corresponds to the effective touch area information.

Accordingly, through the interface with the server 400, the processor 110 may restrict the partial area of the touch screen panel 120, which corresponds to the view window of the cover 200b, to the effective touch area when the cover 200b is closed.

Namely, the electronic device, according to various embodiments of the present disclosure, may perform the certification operation of determining whether the cover is a genuine product or not autonomously or through the interface with the server 400 that is connected thereto through the network.

Further, the electronic device may perform the recognition operation of recognizing the shape, size, location coordinates, etc. of the view window of the cover autonomously or through the interface with the server 400 that is connected thereto through the network. Meanwhile, a wider variety of methods for recognizing the view window of the cover may exist, and will be described below in detail.

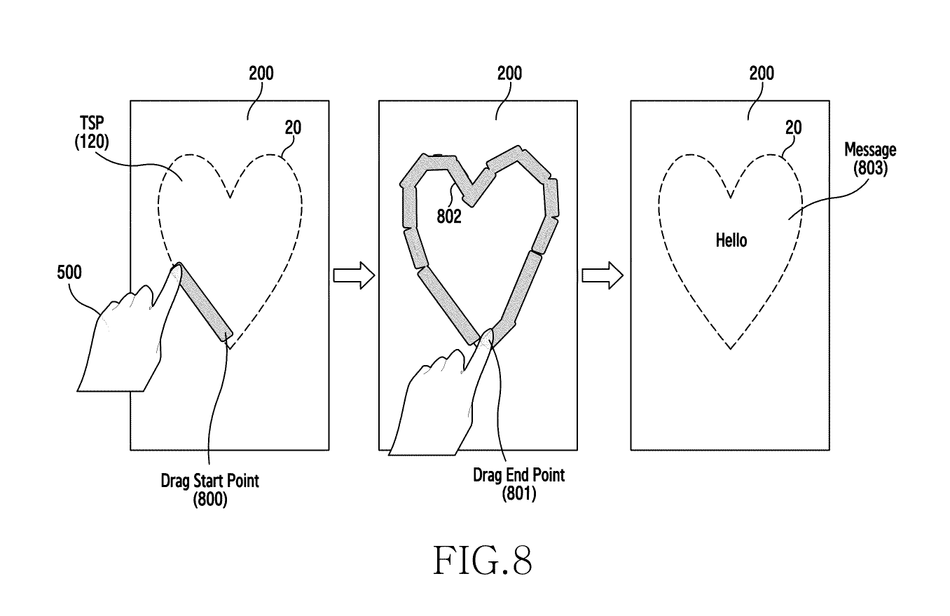

FIG. 8 is a diagram illustrating a method of recognizing a view window of a cover according to various embodiments of the present disclosure. Referring to FIG. 8, a cover 200 mounted on an electronic device, such as a smart phone, etc., may have, for example, a heart-shaped view window 20 formed therein.

The electronic device equipped with the cover 200 may output a video guidance message or an audio guidance message in order to recognize, for example, the shape, size, location coordinates, etc. of the view window 20 of the cover 200.

The user of the electronic device may close the cover 200, which is mounted on the electronic device, with reference to the video guidance message, the audio guidance message, etc. and then, as illustrated in FIG. 8, the user may seamlessly perform a series of continuous drag operation of starting a drag from one arbitrary point in a partial area of a touch screen panel 120 that is exposed through the view window 20 of the cover 200 and ending the drag at the point.

A processor 110 of the electronic device may recognize image information that corresponds to the user's drag values that are detected along the periphery of the view window 20 of the cover 200, and may set the partial area of the touch screen panel 120, which corresponds to the recognized image information, as an effective touch area when the cover 200 is closed.

Here, when the drag start point 800 coincides with the drag end point 801, and the drag 802 is seamlessly performed on the path between the drag start point and the drag end point, the processor 110 may determine the user's drag values to be effective values for recognizing the view window 20 of the cover 200.

When the shape, size, location coordinates, etc. of the view window 20 of the cover are normally recognized through the above-described process, the processor 110 may allow various forms of messages 803 (e.g., Hello) for informing that the view window has normally been recognized to be displayed in the partial area of the touch screen panel 120, which corresponds to the view window 20, as illustrated in FIG. 8.

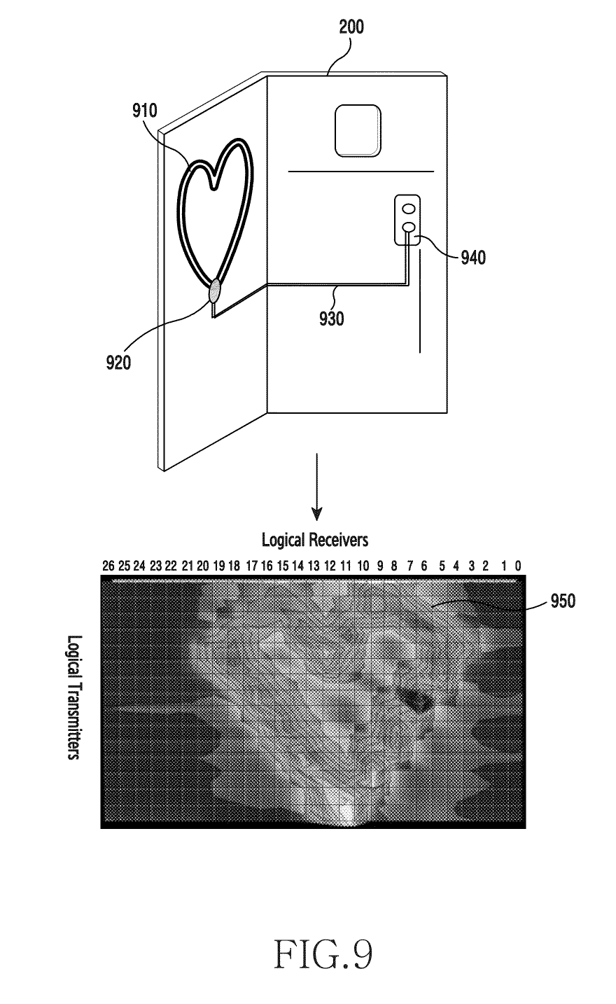

FIG. 9 is a diagram illustrating another method of recognizing a view window of a cover 200 according to various embodiments of the present disclosure. Referring to FIG. 9, a cover 200 mounted on an electronic device, such as a smart phone, etc., may have, for example, a heart-shaped view window formed therein, and a heart-shaped conductive pattern 910 may be mounted on the inside of the cover along the periphery of the view window. Here, the remaining area of the cover 200 other than the view window may be formed of a non-conductive material (e.g., leather, plastic, etc.)

As illustrated in FIG. 9, the conductive pattern 910 may be connected to a circuit element 940, which is mounted on the rear plate of the cover, through a signal line 930 that is connected thereto through a GND 920. The circuit element 940 may be a Near Field Communication (NFC) IC by which the cover is operated in conjunction with the electronic device by an electrical signal, and unique cover information allocated to the cover may be stored in the circuit element 940.

The electronic device equipped with the cover 200 may output a video guidance message or an audio guidance message in order to recognize, for example, the shape, size, location coordinates, etc. of the view window 20 of the cover 200. For example, the user of the electronic device may set the operating mode of the electronic device to a view window recognition mode with reference to the video guidance message or the audio guidance message, and may then close the cover 200, which is mounted on the electronic device.

When the cover 200 is closed while the view window recognition mode is set, a processor 110 of the electronic device may recognize, as illustrated in FIG. 9, image information 950 that corresponds to the view window 20 based on the sensitivity of a touch screen panel 120 that is detected by the characteristic of the conductive material that is mounted on the inside of the cover along the periphery of the view window of the cover.

The processor 110 may set a partial area of the touch screen panel 120, which corresponds to the recognized image information 950, as an effective touch area when the cover 200 is closed, and may operate in conjunction with the TSP controller 130 to activate only the partial area of the touch screen panel 120, which corresponds to the set effective touch area, when the cover 200 is closed.

In addition, every time the cover 200 is closed, or when a user makes a request for identification, the processor 110 may recognize image information corresponding to the view window based on the sensitivity of the touch screen panel that is detected by the conductive material that is mounted on the inside of the cover along the periphery of the view window 20.

Further, the processor 110 may determine whether the currently recognized image information of the view window agrees with the previously recognized image information of the view window, and if not, the processor 110 may determine that a new cover having a different view window formed therein has been newly mounted on the electronic device.

The processor 110 may perform at least one of outputting a message for informing of the determination result, making the previously set effective touch area invalid, and automatically setting an effective touch area that corresponds to the view window of the new cover.

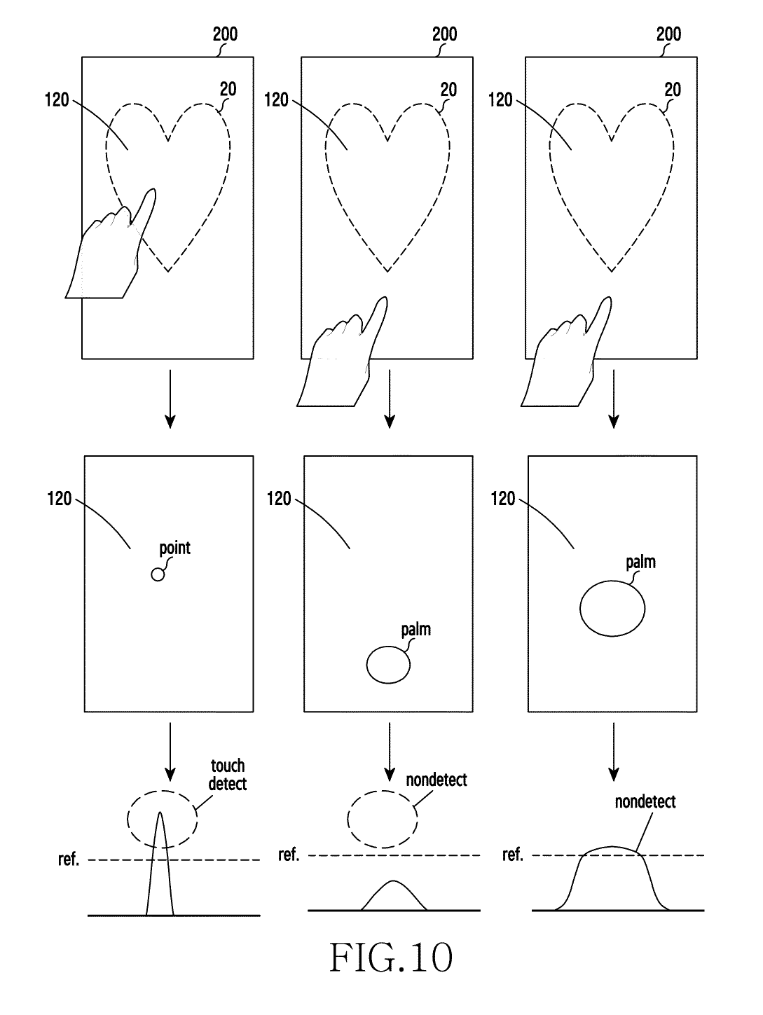

FIG. 10 is a diagram illustrating a method of processing an input touch according to various embodiments of the present disclosure. Referring to FIG. 10, an electronic device, such as a smart phone, etc., may be equipped with, for example, a cover 200 that has a heart-shaped view window 20 formed therein.

The user of the electronic device may normally touch a partial area of a touch screen panel 120 of the electronic device that is exposed to the outside through the heart-shaped view window 20 while the cover 200 is closed.

In this case, a point type of touch may be detected on the touch screen panel 120, and the point type of touch signal is detected to have a higher level than a preset reference threshold value so that a processor 110 may recognize the touch signal as a normal touch detection signal.

In contrast, the user of the electronic device may unconsciously touch another area of the touch screen panel 120 that is not exposed to the outside through the heart-shaped view window 20 while the cover 200 is closed.

In this case, a palm type of touch may be detected on the touch screen panel 120, and since the palm type of touch signal is detected to have a lower level than the preset reference threshold value, the palm type of touch signal cannot be recognized as a normal touch detection signal by the processor 110, which makes it possible to prevent an unnecessary malfunction from being generated.

According to an exemplary embodiment of the present disclosure, the view window of the cover may be formed of a different material from the remaining area of the cover other than the view window so that, when a touch is input to the remaining area of the cover other than the view window, the touch input pattern may be diversely processed by using the difference between actual contact surfaces that the touch screen panel recognizes

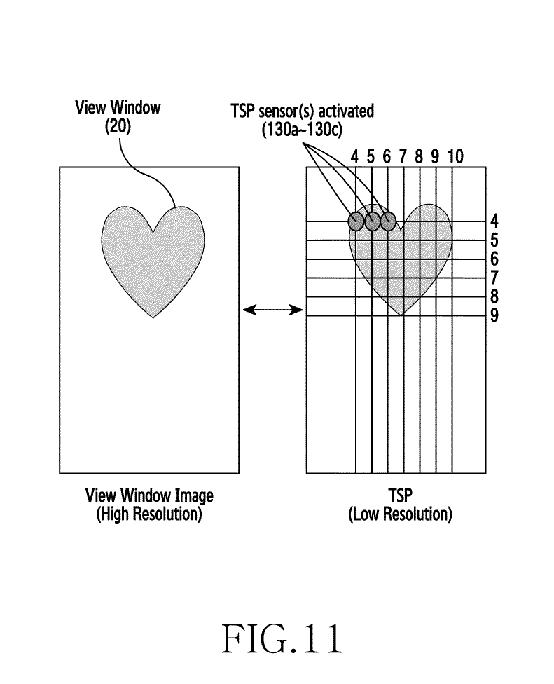

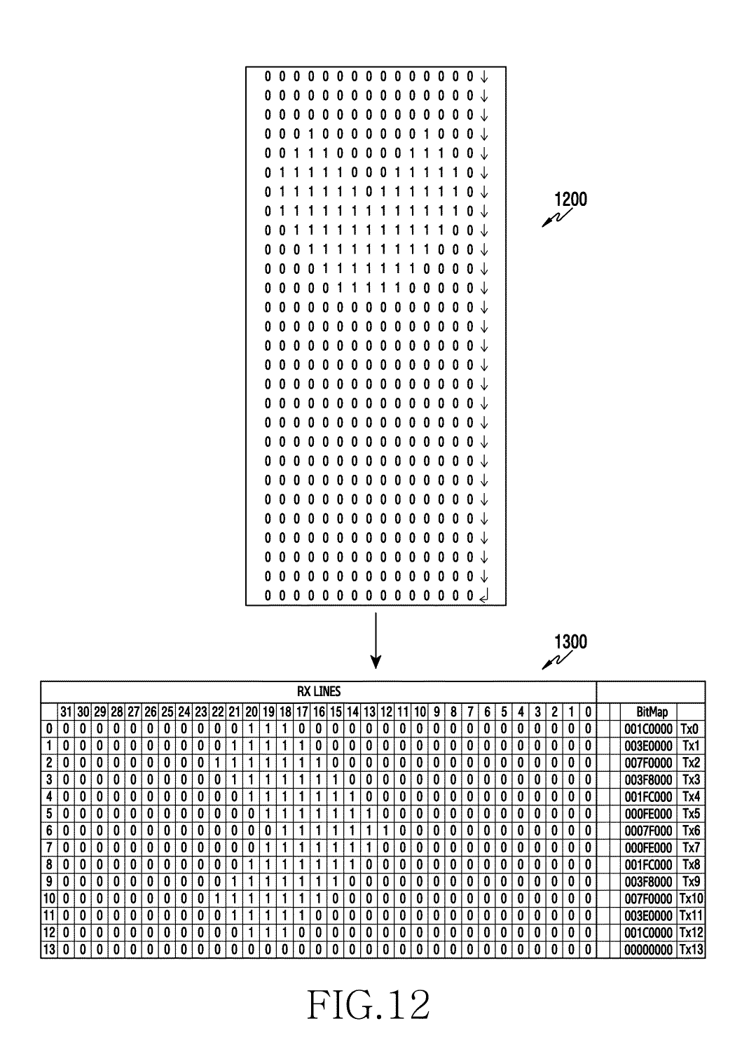

FIG. 11 is a diagram illustrating a difference in resolution between a view window image and a touch screen panel according to various embodiments of the present disclosure, and FIG. 12 is a diagram illustrating a view window image that is converted to have a low resolution and effective touch area information of a touch screen panel according to various embodiments of the present disclosure.

Referring to FIG. 11, a cover mounted on an electronic device, such as a smart phone, etc., may have, for example, a heart-shaped view window 20 formed therein, and recognition information that represents the shape, size, location coordinates, etc. of the view window 20 may be a view window image with a high resolution in which the heart shape is included.

A processor 110 of the electronic device may recognize the shape, size, location coordinates, etc. of the view window 20 by scanning the high-resolution view window image, and may set a partial area of a touch screen panel, which corresponds to the view window, as an effective touch area when the cover is closed.

The touch screen panel 120, which has a lower resolution than the image of the view window 20, may have a mesh structure in which a plurality of touch sensors 130a to 130c are arranged in the horizontal (X-axis) direction and the vertical (Y-axis) direction. The processor 110, when scanning the high-resolution view window image, may apply a down scanning algorithm such that the low-resolution touch screen panel and the high-resolution view window image match each other.

Referring to FIG. 12, the image 1200 of the view window that is converted from a high resolution to a low resolution by a down scanning algorithm as described above may match effective touch area information 1300 for selectively activating the plurality of touch sensors that are arranged on the touch screen panel in the horizontal and vertical directions.

The processor 110 may transmit the effective touch area information 1300 to a TSP controller 130 after generating the effective touch area information 1300 of the touch screen panel through the matching process. Meanwhile, the processor 110 may transmit image information of the view window to the TSP controller 130, and the TSP controller 130 may make the low-resolution touch screen panel and the high-resolution view window image match each other.

However, considering that data processing capability of the processor 110 is higher than that of the TSP controller 130, the processor 110 may preferably perform the operation of matching the low-resolution touch screen panel and the high-resolution view window image.

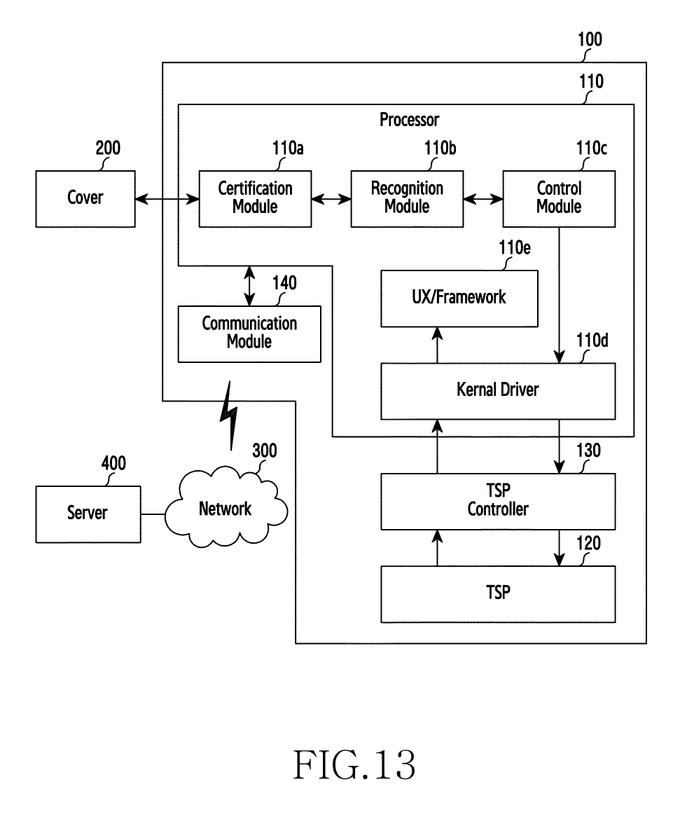

FIG. 13 is a block diagram of the whole configuration of an electronic device according to various embodiments of the present disclosure. Referring to FIG. 13, the electronic device 100 may be, for example, a smart phone, etc. The electronic device 100 may include a processor 110, a touch screen panel 120, a TSP controller 130, a communication module 140, etc., and the TSP controller 130 may be manufactured in various forms, such as an IC, a module, etc. that operates in conjunction with the processor 110.

The processor 110 may be operated in conjunction with an external accessory, for example a cover 200, which is mounted on the electronic device 100, by an electrical signal wherein the cover 200 has various forms of view windows formed therein. In cases where the electronic device 100 is equipped with the cover 200, the processor 110 may set a partial area of the touch screen panel 120, which corresponds to the view window of the cover 200, as an effective touch area when the cover 200 is closed.

The processor 110 may operate in conjunction with the TSP controller 130 to activate only the partial area of the touch screen panel 120, which corresponds to the set effective touch area, when the cover 200 is closed. As illustrated in FIG. 13, the processor 110 may be functionally divided into a certification module 110a, a recognition module 110b, a control module 110c, a kernel driver 110d, a UX/Framework 110e, etc. For example, the certification module 110a may certify whether the cover 200 is a genuine product or not through communication with the cover 200, and in cases where the cover 200 is a genuine product, the recognition module 110b may recognize the shape, size, location coordinates, etc. of the view window formed in the cover 200.

Here, the function of certifying whether the cover is a genuine product or not and the function of recognizing the shape, size, location coordinates, etc. of the view window may be performed by an interface with a server 400, which is connected through a network 300, in conjunction with the communication module 140.

The control module 110c may set the partial area of the touch screen panel 120, which corresponds to the recognized view window, as an effective touch area when the cover 200 is closed, and may operate in conjunction with the TSP controller 130 to activate only the partial area of the touch screen panel 120, which corresponds to the set effective touch area, when the cover 200 is closed.

The kernel driver 110d may relay data transmission/reception between the control module 110c and the TSP controller 130, and the UX/Framework 110e may provide various functions that a user wants by executing an application that corresponds to a touch input that is entered through the kernel driver 110d.

In cases where the electronic device 100 is equipped with the cover 200, the processor 110 may communicate with the cover 200 to acquire unique cover information allocated to the cover 200. Here, the communication with the cover may be performed by using a typical contact scheme or an NFC scheme, and through the communication, the unique cover information may be read from an NFC IC, which is installed on the rear plate of the cover, in a pairing scheme.

The unique cover information may include certification information required by the processor 110 to determine, through the interface with the server 400, whether the cover 200 is a normal product that can electrically interwork with the electronic device 100. For example, the certification information may be a unique code, such as a serial number, etc. that the manufacturer of the cover 200 and the manufacturer of the electronic device 100 has assigned in advance.

Further, the unique cover information may include recognition information required by the processor 110 to recognize the shape, size, location coordinates, etc. of the view window, which is formed in the cover 200, through the interface with the server 400. For example, the recognition information may be code values, for example the shape code, the size code, the location coordinate code, etc., which represent the shape, size, location coordinates, etc. of the view window formed in the cover 200, or may be image information that represents the shape, size, location coordinates, etc. of the view window at one time.

The processor 110 may certify whether the cover 200 is a genuine product or not through the interface with the server 400 based on the certification information included in the unique cover information. For example, the processor 110 may generate the certification information included in the unique cover information and a certification request message, and may transmit the generated certification information and certification request message to the server 400.

In response to the certification request message, the server 400 may identify whether the certification information of the cover 200 has been stored in, for example, a genuine-product certification database and thereafter, may generate a certification response message that corresponds to the identification result and transmit the generated certification response message to the processor 110 of the electronic device. The processor 110 may allow an error message to be displayed when the certification response message shows that the certification has failed.

If the certification response message shows that the certification has succeeded, the processor 110 may perform a view window recognition operation of recognizing the shape, size, location coordinates, etc. of the view window, which is formed in the cover 200, through the interface with the server 400 based on the recognition information included in the unique cover information.

For example, the processor 110 may transmit, to the server 400, the shape code, the size code, the location coordinate code, etc. that have been acquired as the recognition information for the view window, or may transmit, to the server 400, the image information that has been acquired as the recognition information for the view window. Further, the processor 110 may generate a recognition request message, in addition to the recognition information, and may transmit the same to the server 400.

In response to the recognition request message, the server 400 may set a partial area of the touch screen panel, which corresponds to the shape, size, location coordinates, etc. of the view window, as an effective touch area and thereafter, may generate information on the effective touch area and a recognition response message and transmit the generated information and recognition response message to the processor 110 of the electronic device.

The processor 110 may control an activation area for the touch screen panel 120 based on the information on the effective touch area, which is received together with the recognition response message. For example, when the cover 200 is closed, the processor 110 may operate in conjunction with the TSP controller 130 to activate only the partial area of the touch screen panel 120 that corresponds to the effective touch area information.

In addition, when the cover 200 is closed, the processor 110 may operate in conjunction with the TSP controller 130 to increase the touch sensitivity for the partial area of the touch screen panel, which corresponds to the view window, to be higher than a preset reference sensitivity. In contrast, when the cover 200 is changed from a closed state to an open state, the processor 110 may operate in conjunction with the TSP controller 130 to reset the touch sensitivity for the partial area of the touch screen panel, which corresponds to the view window, to the preset reference sensitivity.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A method of operating an electronic device, the method comprising:
setting a partial area of a touch screen panel, that corresponds to a view window of a cover mounted on the electronic device, as an effective touch area when the cover is closed; and
when the cover mounted on the electronic device is closed, activating the partial area of the touch screen panel that corresponds to the set effective touch area.

2. The method of claim 1, further comprising:
determining whether the cover is a genuine product through communication with the cover mounted on the electronic device.

3. The method of claim 2, wherein the determining comprises:
acquiring unique cover information allocated to the cover, through the communication with the cover mounted on the electronic device; and
determining, by the electronic device, whether the cover is a genuine product, autonomously or through communication with a server connected thereto through a network, based on the unique cover information.

4. The method of claim 1, further comprising:
detecting only a touch that occurs in the activated partial area of the touch screen panel as a touch input.

5. The method of claim 1, wherein the setting comprises:
acquiring unique cover information allocated to the cover through communication with the cover mounted on the electronic device;
recognizing image information that corresponds to the view window of the cover based on the unique cover information; and
setting a partial area of the touch screen panel, which corresponds to the recognized image information as the effective touch area when the cover is closed.

6. The method of claim 5, wherein the image information comprises one or more of a shape, a size, and location coordinates of the view window of the cover mounted on the electronic device and is recognized by the electronic device autonomously or through communication with a server connected thereto through a network.

7. The method of claim 1, wherein the setting comprises:
recognizing image information that corresponds to drag values of a user drag that are detected along a periphery of the view window of the cover mounted on the electronic device; and
setting a partial area of the touch screen panel that corresponds to the recognized image information as the effective touch area when the cover is closed.

8. The method of claim 7, wherein the drag values are determined to be effective values when a drag start point coincides with a drag end point, and the drag is seamlessly performed along the path between the drag start point and the drag end point.

9. The method of claim 1, wherein the setting comprises:
setting the partial area of the touch screen panel, that corresponds to the view window of the cover, as the effective touch area when the cover is closed according to a characteristic of a conductive material that is mounted on an inside of the cover along a periphery of the view window of the cover.

10. An electronic device comprising:
a touch screen panel;
a controller configured to control the touch screen panel; and
a processor coupled to the controller, the processor configured to:
set a partial area of the touch screen panel, that corresponds to a view window of a cover mounted on the electronic device, as an effective touch area when the cover is closed; and
activate the partial area of the touch screen panel, which corresponds to the set effective touch area, in conjunction with the controller when the cover mounted on the electronic device is closed.

11. The electronic device of claim 10, wherein the processor is further configured to determine whether the cover is a genuine product or through communication with the cover mounted on the electronic device.

12. The electronic device of claim 11, wherein the processor is further configured to:
acquire unique cover information allocated to the cover, through the communication with the cover mounted on the electronic device, and
determine whether the cover is a genuine product, autonomously or through communication with a server connected thereto through a network, based on the unique cover information.

13. The electronic device of claim 10, wherein the processor is further configured to detect only a touch that occurs in the activated partial area of the touch screen panel, as a touch input in conjunction with the controller.

14. The electronic device of claim 10, wherein the processor is further configured to:
acquire unique cover information allocated to the cover through communication with the cover mounted on the electronic device,
recognize image information that corresponds to the view window of the cover based on the unique cover information, and
operate in conjunction with the controller to set a partial area of the touch screen panel that corresponds to the recognized image information as the effective touch area when the cover is closed.

15. The electronic device of claim 14, wherein the processor is further configured to decrease the resolution of the image information according to the resolution of the touch screen panel, and send the image information with the decreased resolution to the controller.

16. The electronic device of claim 14, wherein the image information comprises one or more of a shape, a size, and location coordinates of the view window of the cover mounted on the electronic device and is recognized by the processor autonomously or through communication with a server connected thereto through a network.

17. The electronic device of claim 10, wherein the processor is further configured to:
recognize image information that corresponds to drag values of a user drag that are detected along a periphery of the view window of the cover mounted on the electronic device, and
operate in conjunction with the controller to set a partial area of the touch screen panel that corresponds to the recognized image information as the effective touch area when the cover is closed.

18. The electronic device of claim 17, wherein the processor is further configured to determine the drag values to be effective values when a drag start point coincides with a drag end point, and the drag is seamlessly performed along the path between the drag start point and the drag end point.

19. The electronic device of claim 10, wherein the processor is further configured to set the partial area of the touch screen panel that corresponds to the view window of the cover, as the effective touch area when the cover is closed, according to the characteristic of a conductive material that is mounted on the inside of the cover, which is mounted on the electronic device, along the periphery of the view window of the cover.

20. A non-transitory computer-readable storage medium that has a program stored therein that when executed a processor, causes an electronic device to:
setting, by an electronic device, a partial area of a touch screen panel, that corresponds to a view window of a cover mounted on the electronic device, as an effective touch area when the cover is closed; and
when the cover that is mounted on the electronic device is closed, activate the partial area of the touch screen panel that corresponds to the set effective touch area.
